(19) United States
(12) Patent Application Publication
(10) Pub. No.: US 2024/0314918 A1
(43) Pub. Date: Sep. 19, 2024

(54) ENGAGING CONNECTION STRUCTURE AND ENGAGING CONNECTION METHOD THEREOF

(71) Applicant: FIVETECH TECHNOLOGY INC., New Taipei City (TW)

(72) Inventors: TING-JUI WANG, New Taipei City (TW); HSIEN-CHANG CHEN, New Taipei City (TW)

(21) Appl. No.: 18/427,840

(22) Filed: Jan. 31, 2024

(30) Foreign Application Priority Data
Mar. 17, 2023 (TW) 112110094

(51) Int. Cl. H05K 1/02

(52) U.S. Cl. CPC H05K 1/0203; H05K 2201/10393; H05K 2201/2072

(57) ABSTRACT

An engaging connection structure and an engaging connection method thereof are introduced. The engaging connection structure includes a base and a fit engaging mechanism. The base is disposed at an object, and the fit engaging mechanism is movably disposed at the base. The base limits the fit engaging mechanism to engaging connect an engaged object disposed at an object or the base releases the fit engaging mechanism to disengage the engaged object disposed at the object. Thus, the base can be disposed at the object, and the fit engaging mechanism can engage connect or disengage the engaged object, thereby completing quick coupling and separation of at least two objects and hence achieving the effect of repeated quick coupling and separation.

### CROSS-REFERENCE TO RELATED APPLICATION

This non-provisional application claims priority under 35 U.S.C. § 119(a) on Patent Application No(s). 112110094 filed in Taiwan, R.O.C. on Mar. 17, 2023, the entire contents of which are hereby incorporated by reference.

### BACKGROUND OF THE INVENTION

### 1. Field of the Invention

The present disclosure provides an engaging connection structure and an engaging connection method thereof, and in particular to an engaging connection structure for repeatedly and quickly coupling and separating at least two objects.

### 2. Description of the Related Art

In general, when at least one object is to be coupled, lock connection is usually performed using a screw for coupling the object.

In the conventional fixing means above, although at least one object can be fixed and coupled in a form that is not easily separated, in addition to unhandy assembly, the least one object may not be easily removed due to the fixed coupling means using the screw.

### BRIEF SUMMARY OF THE INVENTION

In view of the prior art above, the inventor provides an engaging connection structure and an engaging connection method thereof in aim of achieving effects of repeated and quickly coupling and separation.

To achieve the above and other objects, the present disclosure provides an engaging connection structure and an engaging connection method thereof, wherein the engaging connection structure includes a base and a fit engaging mechanism. The base is disposed at an object, and the fit engaging mechanism is movably disposed at the base. The base limits the fit engaging mechanism to engaging connect an engaged object, or the base releases the fit engaging mechanism to disengage the engaged object.

The present disclosure further provides another engaging connection structure and an engaging connection method thereof, wherein the engaged object is first horizontally or rotatably inserted into a connector, and then the fit engaging mechanism coordinating with the base is used to fit engage and limit or limit the engaged object.

The present disclosure further provides another engaging connection structure and an engaging connection method thereof, wherein the engaged object is horizontally or rotationally inserted into a connector, while the fit engaging mechanism coordinating with the base is used to fit engage and limit or limit the engaged object.

The present disclosure further provides another engaging connection structure and an engaging connection method thereof, wherein the engaged object is first fit engaged and limited or limited by the fit engaging mechanism coordinating with the base, and is then horizontally or rotationally inserted into a connector.

In the engaging connection structure and an engaging connection method thereof above, the base is provided with at least one assembly portion to assemble the base at an object.

In the engaging connection structure and an engaging connection method thereof above, the assembly portion is assembled at an object by lock connection, rivet connection, expansion connection, weld connection or adhesion connection.

In the engaging connection structure and an engaging connection method thereof above, the assembly portion is provided with a screw lock portion, which coordinates with a fixing element to assemble the base at the object.

In the engaging connection structure and an engaging connection method thereof above, the number of the assembly portion is two, and the two assembly portions are respectively disposed on two ends of the base.

In the engaging connection structure and an engaging connection method thereof above, the base and the fit engaging mechanism are movably assembled by a bolt or a bolt member in between.

In the engaging connection structure and an engaging connection method thereof above, the base is provided with a movable region, and the fit engaging mechanism is movably disposed in the movable region.

In the engaging connection structure and an engaging connection method thereof above, the movable region limits a rotation angle of the fit engaging mechanism to be between 10 degrees and 170 degrees.

In the engaging connection structure and an engaging connection method thereof above, the base is provided with a through hole which is in communication with the movable region, and the fit engaging mechanism is provided with a notch which is configured to be in communication with a pivotal hole. The notch is disposed in the movable region, the pivotal hole corresponds to the through hole, and the pivotal hole and the through hole are movably assembled by a bolt or a bolt member in between.

In the engaging connection structure and an engaging connection method thereof above, the base is provided with an elastic engaging portion, which limits or releases the fit engaging mechanism.

In the engaging connection structure and an engaging connection method thereof above, the elastic engaging portion is provided with an engaging body and an elastic body. The elastic body is disposed at the base, the engaging body is disposed at the elastic body, and the elastic body provides the engaging body with reciprocating elasticity for the elastic engaging portion to limit or release the fit engaging mechanism by the engaging body.

In the engaging connection structure and an engaging connection method thereof above, the elastic engaging portion is provided with an operating portion, and a force can be applied to the operating portion to move the engaging body to limit or release the fit engaging mechanism.

In the engaging connection structure and an engaging connection method thereof above, one side of the base corresponding to the engaged object is provided with a limiting guide portion, which can guide and limit the engaged object.

In the engaging connection structure and an engaging connection method thereof above, the limiting guide portion is a stopper, a fastener, a groove, a slide rail, a track, a recess or a protrusion.

In the engaging connection structure and an engaging connection method thereof above, the fit engaging mechanism is provided with a trigger portion, and a force can be applied to the trigger portion for the fit engaging mechanism to be engaging connected to the engaged object, or a force can be applied to the trigger portion for the fit engaging mechanism to be disengaged from the engaged object.

In the engaging connection structure and an engaging connection method thereof above, the fit engaging mechanism is provided with a limiting portion, which is abutted against and engaging connected to the engaged object or is removed from and disengaged from the engaged object.

In the above engaging connection structure and the engaging connection method thereof, the fit engaging mechanism is disposed at an object, and the object or the engaged object is a circuit board, a metal board, a plastic board, a board card, a printed circuit board (PCB), an M.2 card, an E1.S card, an NIC card, an integrated circuit (IC), a chip, a memory card, a cooling fin, a cooling card or a heat sink. In the above engaging connection structure and the engaging connection method thereof, the engaged object is an electronic device having a heat sink.

In the engaging connection structure and an engaging connection method thereof above, the fit engaging mechanism is provided with at least one engaging receiving portion, the engaged portion is provided with at least one counterpart engaging portion, and the engaging receiving portion is engaging connected with the counterpart engaging portion.

In the engaging connection structure and an engaging connection method thereof above, an elastic element is provided between the fit engaging mechanism and the base. The elastic element is used to elastically release the fit engaging mechanism, or the elastic element is used to automatically elastically release the fit engaging mechanism.

In the engaging connection structure and an engaging connection method thereof above, the fit engaging mechanism has an arched arm structure, and the engaged object is engaging connected, or one side of a majority of the engaged object is engaging connected, or all of one side of the engaged object is engaging connected, or one side of a minority of the engaged object is engaging connected by the arched arm structure.

In the engaging connection structure and an engaging connection method thereof above, another limiting guide portion is provided at an object, or the another limiting guide portion corresponds to the base, or the another limiting guide portion is a stopper, a fastener, a groove, a slide rail, a track, a step, a recess or a protrusion.

Thus, with the engaging connection structure and an engaging connection method thereof above, the base can be disposed at the object and can be engaging connected with or disengaged from the engaged object using the fit engaging mechanism, thereby completing quick coupling and separation of at least two objects and hence achieving the effect of repeated quick coupling and separation.

### BRIEF DESCRIPTION OF THE DRAWINGS

FIG. 1 is an exploded schematic diagram according to a first embodiment of the present disclosure.

FIG. 2 is a schematic diagram of an appearance according to the first embodiment of the present disclosure.

FIG. 3 is a first schematic diagram of a state of use according to the first embodiment of the present disclosure.

FIG. 4 is a second schematic diagram of a state of use according to the first embodiment of the present disclosure.

FIG. 5 is a third schematic diagram of a state of use according to the first embodiment of the present disclosure.

FIG. 6 is a schematic diagram of a state of use according to a second embodiment of the present disclosure.

FIG. 7 is a schematic diagram of a state of use according to a third embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

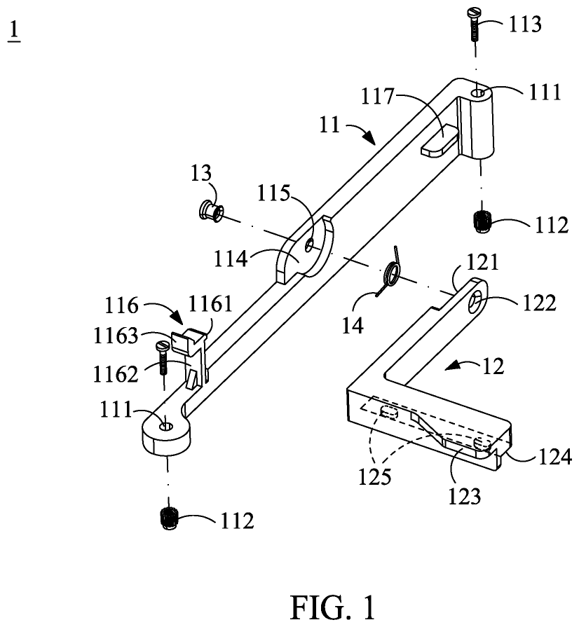

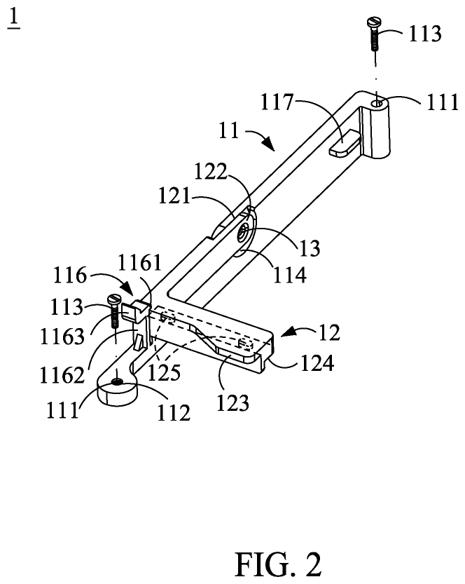

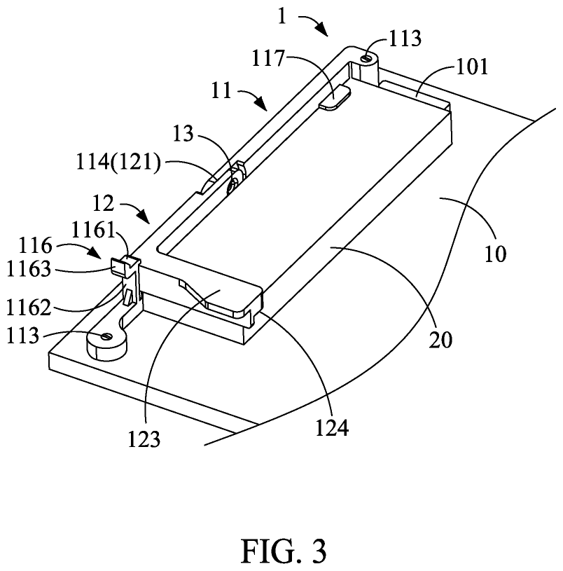

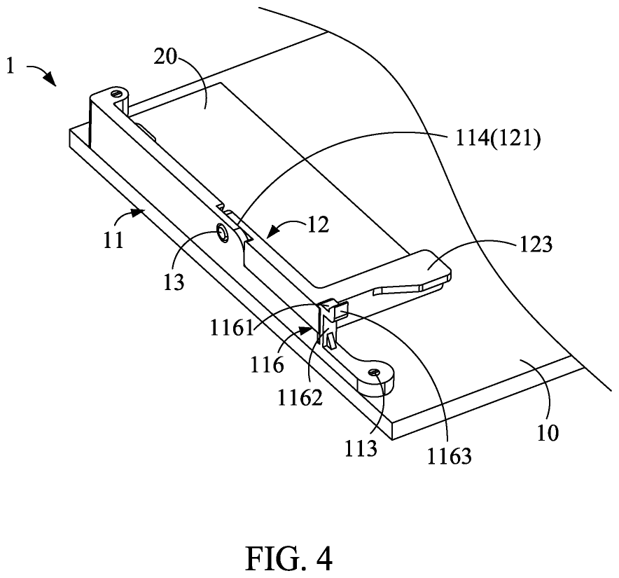

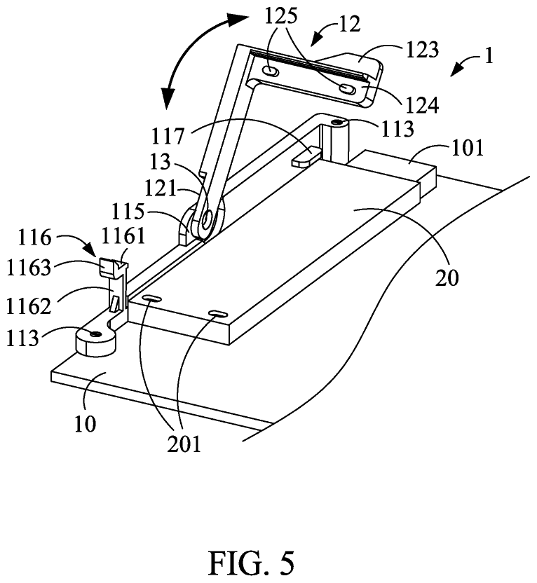

Referring to FIG. 1 to FIG. 5, as shown in the drawings, the present disclosure provides an engaging connection structure and an engaging connection method thereof. The engaging connection structure 1 includes a base 11 and at least one fit engaging mechanism 12.

The base 11 is disposed at an object 10.

The fit engaging mechanism 12 is movably disposed at the base 11, and the base 11 limits the fit engaging mechanism 12 to engaging connect an engaged object 20 disposed at the object 10, or the base 11 releases the fit engaging mechanism 12 to disengage the engaged object 20 disposed at the object 10.

In addition to the embodiments above, in one embodiment of the present disclosure, the object 10 or the engaged object 20 can be a circuit board, a metal board, a plastic board, a board card, a printed circuit board (PCB), an M.2 card, an E1.S card, an NIC card, an integrated circuit (IC), a chip, a memory card, a cooling fin, a cooling card or a heat sink, and the object 10 can be provided with a connector 101.

In addition to the above embodiments, in one embodiment of the present disclosure, the engaged object 20 is an electronic device having a heat sink.

In addition to the above embodiments, in the engaging connection method of the present disclosure, the engaged object 20 is first horizontally (or rotationally) inserted into the connector 101, and then the fit engaging mechanism 12 coordinating with the base 11 is used to fit engage and limit or limit the engaged object 20.

In addition to the above embodiments, in the engaging connection method of the present disclosure, the engaged object 20 is horizontally or rotationally inserted into the connector 101, while the fit engaging mechanism 12 coordinating with the base 11 is used to fit engage and limit or limit the engaged object 20.

In addition to the above embodiments, in the engaging connection method of the present disclosure, the engaged object 20 is first fit engaged and limited or limited by the fit engaging mechanism 12 coordinating with the base 11, and is then horizontally or rotationally inserted into the connector 101.

To put to the engaging connection structure 1 of the present disclosure to use, the base 11 can be fixed at the object 10, the engaged object 20 is assembled at the connector 101, and then the fit engaging mechanism 12 is engaging connected to one end of the engaged object 20. Once engaging connected to the engaged object 20, the fit engaging mechanism 12 can be limited by the base 11, such that the fit engaging mechanism 12 can securely engaging connect the engaged object 20.

To remove the engaged object 20, the base 11 is caused to release the fit engaging mechanism 12, so that the fit engaging mechanism 12 can separate and release the engaged object 20 to remove the engaged object 20 from the connector 101, thereby completing quick coupling and separation of at least two objects and hence achieving the effect of repeated quick coupling and separation.

In addition to the embodiments above, in one embodiment of the present disclosure, the base 11 is provided with at least one assembly portion 111, which is for the base 11 to be assembled at the object 10. In this embodiment, the number of the assembly portion 111 is two, which are respectively disposed on two ends of the base 11. Moreover, the assembly portion 111 is provided with a screw lock portion 112, which coordinates with a fixing element 113 for the base 11 to be assembled at the object 10. Thus, the base 11 can be securely assembled at the object 10 to facilitate subsequent operations of the fit engaging mechanism 12.

In addition to the embodiments above, in one embodiment of the present disclosure, the base 11 can be assembled at the object 10 by the assembly portion 111 by means of lock connection, rivet connection, expansion connection, welding connection or adhesion connection. Thus, the base 11 can be securely assembled at the object 10 according to actual requirements.

In addition to the embodiments above, in one embodiment of the present disclosure, the base 11 and the fit engaging mechanism 12 can be movably assembled by a bolt 13 (or a bolt member) in between. Thus, the fit engaging mechanism 12 coordinating with the bolt 13 can move downward, be engaging connected on one end of the engaged object 20 and be limited by the base 11, so that the fit engaging mechanism 12 can securely engage connect the engaged object 20. Or, the base 11 is caused to release the fit engaging mechanism 12 for the fit engaging mechanism 12 coordinating with the bolt 13 to move upward, so that the fit engaging mechanism 12 can separate and disengage the engaged object 20 to remove the engaged object 20 from the connector 101, thereby completing quick coupling and separation of at least two objects and hence achieving the effect of repeated quick coupling and separation.

In addition to the embodiments above, in one embodiment of the present disclosure, the base 11 is provided with a movable region 114, the fit engaging mechanism 12 is movably disposed in the movable region 114, and the movable region 114 limits a rotation angle of the fit engaging mechanism 12 to between 10 degrees and 170 degrees. In this embodiment, the base 11 is provided with a through hole 115 which is in communication with the movable region 114, and the fit engaging mechanism 12 is provided with a notch 121 which is configured to be in communication with a pivotal hole 122. The notch 121 is disposed in the movable region 114, the pivotal hole 122 corresponds to the through hole 115, and the pivotal hole 122 and the through hole 115 are movably assembled by the bolt 13 in between. Thus, the fit engaging mechanism 12 coordinating with the bolt 13 by the notch 121 pivotally rotates in the movably region 114, moves downward, becomes engaging connected to one end of the engaged object 20, and is limited by the base 11, so that the fit engaging mechanism 12 can securely engaging connect the engaged object 20. Or, the base 11 is caused to release the fit engaging mechanism 12, and accordingly the fit engaging mechanism 12 coordinating with the bolt 13 by the notch 121 pivotally rotates in the movably region 114, moves upward, and departs from one end of the engaged object 20, so that the fit engaging mechanism 20 can separate and disengage the engaged object 20 to remove the engaged object 20 from the connector 101, thereby completing quick coupling and separation of at least two objects and hence achieving the effect of repeated quick coupling and separation.

In addition to the embodiments above, in one embodiment of the present disclosure, the base 11 is provided with an elastic engaging portion 116, which limits or release the fit engaging mechanism 12. Thus, the fit engaging mechanism 12 coordinating with the bolt 13 by the notch 121 pivotally rotates in the movable region 114, moves downward, becomes engaging connected to one end of the engaged object 20, and is limited by the elastic engaging portion 116 of the base 11, so that the fit engaging mechanism 12 can securely engaging connect the engaged object 20. Or, the elastic engaging portion 116 of the base 11 is caused to release the fit engaging mechanism 12, and accordingly the fit engaging mechanism 12 coordinating with the bolt 13 by the notch 121 pivotally rotates in the movable region 114, moves upward and departs from one end of the engaged object 20, so that the fit engaging mechanism 12 can separate and disengage the engaged object 20 to remove the engaged object 20 from the connector 101, thereby completing quick coupling and separation of at least two objects and hence achieving the effect of repeated quick coupling and separation.

In this embodiment, the elastic engaging portion 116 is provided with an engaging body 1161 and an elastic body 1162. The elastic body 1162 is disposed at the base 11, and the engaging body 1161 is disposed on a top end of the elastic body 1162. The elastic body 1162 provides the engaging body 1161 with reciprocating elasticity for the elastic engaging portion 116 to limit or release the fit engaging mechanism 12 by the engaging body 1161. Thus, the fit engaging mechanism 12 coordinating with the bolt 13 by the notch 121 pivotally rotates in the movable region 114, moves downward, becomes engaging connected to one end of the engaged object 20, and is limited by the elastic engaging portion 116 by the engaging portion 1161 coordinating with the elastic body 1162, so that the fit engaging mechanism 12 can securely engaging connect the engaged object 20. Or, the elastic engaging portion 116 is caused to release the fit engaging mechanism 12 by the engaging body 1161 coordinating with the elastic body 1162, and accordingly the fit engaging mechanism 12 coordinating with the bolt 13 by the notch 121 pivotally rotates in the movable region 114, moves upward and departs from one end of the engaged object 20, so that the fit engaging mechanism 12 separates and disengages the engaged objects 20 to remove the engaged object 20 from the connector 101, thereby completing quick coupling and separation of at least two objects and hence achieving the effect of repeated quick coupling and separation.

In addition to the embodiments above, in one embodiment of the present disclosure, the engaging body 1161 of the elastic engaging portion 116 is provided with an operating portion 1163. A force can be applied to the operating portion 1163 to move the engaging body 1161 to further limit or release the fit engaging mechanism 12, so as to facilitate subsequent operations of the elastic engaging portion 116.

In addition to the embodiments above, in one embodiment of the present disclosure, one side of the base 11 corresponding to the engaged object 20 is provided with a limiting guide portion 117, which can be a stopper, a fastener, a groove, a slide rail, a track, a step, a recess or a protrusion. The limiting guide portion 117 can guide and limit the engaged object 20. Thus, when the engaged object 20 is assembled on the object 10 and connected to the connector 101, the engaged object 20 can be guided by the limiting guide portion 117 and be readily assembled to the connector 101, and can also be limited by the limiting guide portion 117 and be securely assembled to the connector 101, further achieving stability during an assembly process and after assembly for the engaged object 20 by using the limiting guide portion 117.

In addition to the embodiments above, in one embodiment of the present disclosure, the fit engaging mechanism 12 is provided with a trigger portion 123. A force can be applied to the trigger portion 123 for the fit engaging mechanism 12 to be engaging connected to the engaged object 20, or a force can be applied to the trigger portion 123 for the fit engaging mechanism 12 to be disengaged from the engaged object 20, so as to facilitate the operation of the fit engaging mechanism 20. Thus, a force can be applied to the trigger portion 12, and accordingly the fit engaging mechanism 12 coordinating with the bolt 13 by the notch 121 pivotally rotates in the movable region 114, moves downward, becomes engaging connected to one end of the engaged object 20, and is limited by the elastic engaging portion 116 by the engaging portion 1161 coordinating with the elastic body 1162, so that the fit engaging mechanism 12 can securely engaging connect the engaged object 20. Or, the elastic engaging portion 116 is caused to release the fit engaging mechanism 12 by the engaging body 1161 coordinating with the elastic body 1162, a force is applied to the trigger 123, and accordingly the fit engaging mechanism 12 coordinating with the bolt 13 by the notch 121 pivotally rotates in the movable region 114, moves upward and departs from one end of the engaged object 20, so that the fit engaging mechanism 12 separates and disengages the engaged objects 20 to remove the engaged object 20 from the connector 101, thereby completing quick coupling and separation of at least two objects and hence achieving the effect of repeated quick coupling and separation.

In addition to the embodiments above, in one embodiment of the present disclosure, the fit engaging mechanism 12 is provided with a limiting portion 124, which is abutted against and engaging connected to the engaged object 20 or is removed from and disengaged from the engaged object 20. Thus, a force can be applied to the trigger portion 123, and accordingly the fit engaging mechanism 12 coordinating with the bolt 13 by the notch 121 pivotally rotates in the movable region 114 and moves downward to abut and engaging connect the limiting portion 124 on one end of the engaged object 20, and is limited by the elastic engaging portion 116 by the engaging portion 1161 coordinating with the elastic body 1162, so that the fit engaging mechanism 12 can securely engaging connect the engaged object 20. Or, the elastic engaging portion 116 is caused to release the fit engaging mechanism 12 by the engaging body 1161 coordinating with the elastic body 1162, a force is applied to the trigger 123, and accordingly the fit engaging mechanism 12 coordinating with the bolt 13 by the notch 121 pivotally rotates in the movable region 114 and moves upward to move the limiting portion 124 away from one end of the engaged object 20, so that the fit engaging mechanism 12 separates and disengages the engaged objects 20 to remove the engaged object 20 from the connector 101, thereby completing quick coupling and separation of at least two objects and hence achieving the effect of repeated quick coupling and separation.

In addition to the embodiments above, in one embodiment of the present disclosure, the fit engaging mechanism 12 is provided at least one engaging receiving portion 125, the engaged object 20 is provided with at least one counterpart engaging portion 201, and the engaging receiving portion 125 is engaging connected to the counterpart engaging portion 201. Thus, once the engaged object f20 is assembled at the connector 101 on the object 10, a force can be applied to the trigger portion 123, and accordingly the fit engaging mechanism 12 coordinating with the bolt 13 by the notch 121 pivotally rotates in the movable region 114 and moves downward to abut and engaging connect the limiting portion 124 on one end of the engaged object 20, becomes engaging connected to the counterpart engaging portion 201 by the engaging receiving portion 125, and is limited by the elastic engaging portion 116 by the engaging body 1161 coordinating with the elastic body 1162, so that the fit engaging mechanism 12 can securely engage connect the engaged object 20. Or, the elastic engaging portion 116 is caused to release the fit engaging mechanism 12 by the engaging portion 1161 coordinating with the elastic body 1162, a force is applied to the trigger portion 123, and accordingly the fit engaging mechanism 12 coordinating with the bolt 13 by the notch 121 in the movable region 114 and moves upward to move the limiting portion 124 away from one end of the engaged portion 20, and at the same time allowing the engaging receiving portion 125 to be removed from the counterpart engaging portion 201, so that the fit engaging mechanism 12 can separate and disengage the engaged object 20 to remove the engaged object 20 from the connector 101, thereby completing quick coupling and separation of at least two objects and hence achieving an effect of repeated quick coupling and separation.

In addition to the embodiments above, in one embodiment of the present disclosure, an elastic element 14 is provided between the fit engaging mechanism 12 and the base 11. Thus, when the engaging connection structure 1 undergoes the operations above by using the fit engaging mechanism 12, the fit engaging mechanism 12 can be elastically released with the coordination of the elastic element 14, or automatically elastically released with the coordination of the elastic element 14, further achieving an effect of readily operating the fit engaging mechanism 12 by using the elastic element 14.

In addition to the embodiments above, in one embodiment of the present disclosure, the fit engaging mechanism 12 has an arched arm structure, and one side of the engaged object 20 is engaging connected, or one side of a majority of the engaged object 20 is engaging connected, or all of one side of the engaged object is engaging connected, or one side of a minority of the engaged object 20 is engaging connected by the arched arm structure, thereby enabling the fit engaging structure 12 to better meet actual application requirements.

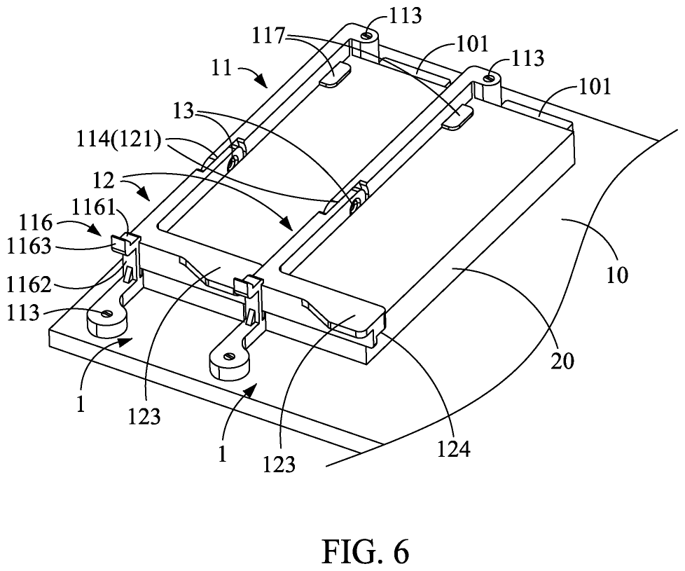

Referring to FIG. 6, as shown in the drawing, in addition to the embodiments above, in one embodiment of the present disclosure, the number of the engaging connection structure 1 is two or more, the engaging connection structures 1 can be arranged side by side at the object 10, and the object 2 is provided with two or more connectors 102 for two or more engaged objects 20 to be arranged. During the arrangement, the method as described above is performed, so that each base 11 coordinating with each fit engaging mechanism 12 can engaging connect each engaged object 20 or disengage each engaged object 20, thereby completing quick coupling and separation of at least two objects and hence achieving an effect of repeated quick coupling and separation, enabling the engaging connection structure 1 of the present disclosure to better meet actual application requirements.

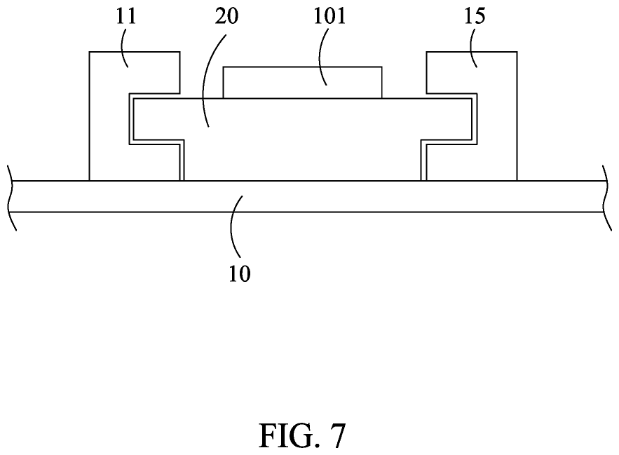

Referring to FIG. 7, as shown in the drawing, in addition to the embodiments above, in one embodiment of the present disclosure, the object 10 is provided with another limiting guide portion 15. The another limiting guide portion 15 corresponds to the base 11, and can be stopper, a fastener, a groove, a slide rail, a track, a recess or a protrusion. Thus, when the engaged object 20 is assembled at the connector 101 on the object 10, the engaged object 20 can be readily assembled to the connector 101 by the guidance of the base 11 and the another limiting guide portion 15, and be securely assembled to the connector 101 by limiting of the base 11 and the another limiting guide portion 15, further achieving stability during an assembly process and after assembly for the engaged object 20 by using the base 11 and the another limiting guide portion 15.

The present invention is described by way of the preferred embodiments above. A person skilled in the art should understand that, these embodiments are merely for describing the present invention are not to be construed as limitations to the scope of the present invention. It should be noted that all equivalent changes, replacements and substitutions made to the embodiments are to be encompassed within the scope of the present invention. Therefore, the scope of protection of the present invention should be accorded with the broadest interpretation of the appended claims.

What is claimed is:

1. An engaging connection structure, comprising:
a base, configured to be disposed at an object;
a fit engaging mechanism, movably disposed at the base, the fit engaging mechanism configured to engaging connect an engaged object, or the fit engaging mechanism configured to disengage the engaged object.

2. The engaging connection structure according to claim 1, wherein the base is provided with at least one assembly portion, the assembly portion is for the base to be assembled at an object, the assembly portion configured to be assembled at the object by lock connection, rivet connection, expansion connection, welding connection and adhesion connection, or the base and the fit engaging mechanism are movably assembled by a bolt or a bolt member in between, or the base is provided with a movable region and the fit engaging mechanism is movably disposed in the movable region, or the movable region limits a rotation angle of the engaging connection structure to be between 10 degrees and 170 degrees.

3. The engaging connection structure according to claim 1, wherein the base is provided with an elastic engaging portion which limits or releases the fit engaging mechanism, or the elastic engaging portion is provided with an engaging body or an elastic body, and the elastic body is disposed at the base, or the engaging body is disposed at the elastic body, or the elastic body provides the engaging body with reciprocating elasticity for the elastic engaging portion to limit or release the fit engaging mechanism by the engaging body, or the elastic engaging portion is provided with an operating portion, and a force can be applied to the operating portion to move the engaging body to limit or release the fit engaging mechanism.

4. The engaging connection structure according to claim 1, wherein the base is provided with a limiting guide portion corresponding to the engaged portion, and the limiting guide portion guides or limits the engaged portion.

5. The engaging connection structure according to claim 1, wherein the fit engaging structure is provided with a trigger portion, and a force can be applied to the trigger to engaging connect the fit engaging mechanism at the engaged object, or a force can be applied to the trigger to disengage the fit engaging mechanism from the engaged object, or the fit engaging mechanism is provided with a limiting portion, and the limiting portion abuts against and is engaging connected at the engaged object, or the limiting portion moves away and disengages from the engaged object, or the fit engaging mechanism is provided with at least one engaging receiving portion, the engaged object is provided with at least one counterpart engaged portion and the engaging receiving portion is engaged connected at the counterpart engaging portion, or the fit engaging mechanism is provided at an object, and the object or the engaged object is a circuit board, a metal board, a plastic board, a board card, a printed circuit board (PCB), an M.2 card, an E1.S card, an NIC card, an integrated circuit (IC), a chip, a memory card, a cooling fin, a cooling card, a heat sink, or an electronic device provided with a heat sink.

6. The engaging connection structure according to claim 1, wherein an elastic element is provided between the fit engaging mechanism and the base, the elastic element is used to elastically release the fit engaging mechanism or the elastic element is used to automatically elastically release the fit engaging mechanism, or the fit engaging mechanism has an arched arm structure, and the engaged object is engaging connected, or one side of a majority of the engaged object is engaging connected, or all of one side of the engaged object is engaging connected, or one side of a minority of the engaged object is engaging connected by the arched arm structure.

7. The engaging connection structure according to claim 1, wherein the object is provided with another limiting guide portion, or the another limiting guide portion corresponds to the base, or the another limiting guide portion is a stopper, a fastener, a groove, a slide rail, a track, a step, a recess or a protrusion.

8. An engaging connection method, performed by the engaging connection structure according to claim 1, wherein the engaged object is first horizontally or rotatably inserted into a connector, and then the fit engaging mechanism coordinating with the base is used to fit engage and limit or limit the engaged object.

9. An engaging connection method, performed by the engaging connection structure according to claim 1, wherein the engaged object is horizontally or rotatably inserted into a connector, while the fit engaging mechanism coordinating with the base is used to fit engage and limit or limit the engaged object.

10. An engaging connection method, performed by the engaging connection structure according to claim 1, wherein the engaged object is first fit engaged and limited or limited by the fit engaging mechanism coordinating with the base, and is then horizontally or rotationally inserted into a connector.
